(19) United States
(12) Patent Application Publication
(10) Pub. No.: US 2020/0041542 A1
(43) Pub. Date: Feb. 6, 2020

(54) TESTING APPARATUS AND TESTING DEVICE

(71) Applicant: HKC Corporation Limited, Shenzhen (CN)

(72) Inventor: Huailiang He, Shenzhen (CN)

(21) Appl. No.: 16/255,862

(22) Filed: Jan. 24, 2019

Related U.S. Application Data
(63) Continuation of application No. PCT/CN2018/115114, filed on Nov. 13, 2018.

(30) Foreign Application Priority Data
Aug. 1, 2018 (CN) 201810861377.4

(51) Int. Cl. G01R 1/04

(52) U.S. Cl. CPC G01R 1/0408

(57) ABSTRACT

The embodiments of the present invention disclose a testing apparatus and a testing device. The testing apparatus includes: a platform body; a supporting plate, fixed on an upper surface of the platform body, and configured to support an array substrate, where the supporting plate includes a plurality of metal plates arranged along a first direction, each of the metal plates extends along a second direction, and the first direction is intersected with the second direction; and a conveying apparatus, configured to convey the array substrate. In the present invention, by disposing a whole block of metal plate in the second direction, and arranging the plurality of metal plates along the first direction to form the supporting plate in the testing apparatus, the flatness of the testing apparatus is guaranteed; and during a test, the testing efficiency may be improved, and a risk of electrostatic discharge is reduced.

### CROSS REFERENCE TO RELATED APPLICATIONS

The present application is a Continuation Application of PCT Application No. PCT/CN2018/115114 filed on Nov. 13, 2018, which claims the benefit of Chinese Patent Application No. 201810861377.4 filed on Aug. 1, 2018. All the above are hereby incorporated by reference.

### FIELD

The embodiments of the present invention relates to the technical field of display testing, and in particular, to a testing apparatus and a testing device.

### BACKGROUND

A Liquid Crystal Display (LCD) is a most common display type at present. Along with the continuous progress of a manufacturing technology, the manufacturing yield of the LCD is also improved. However, it is inevitable that the yield of the current LCD still cannot reach to 100%. With the consideration to the yield, a detection mechanism is increased generally during a manufacturing process so as to improve the yield of the LCD.

A tester may detect a pixel array on the LCD. At present, a supporting plate on a stage testing apparatus in the tester is spliced by a plurality of metal plates that are arranged in multiple rows and columns; and adjacent two metal plates on each column are connected via a buckle. Since it is not ensured that a resistance at a junction of the adjacent two metal plates on each column is within a specified range, a gap between the adjacent two metal plates on each column needs to be adjusted, and whenever a chamber of the tester is opened, the resistance at the junction needs to be measured, thereby being time-consuming. With an excessively large resistance at the junction, there may be an electrostatic focus and a risk of electrostatic discharge, and a to-be-tested product may be damaged. In addition, due to an individual difference of each of the metal plates and a splicing influence, the flatness of the whole stage testing apparatus cannot be guaranteed and the detection on the to-be-tested product is affected.

### SUMMARY

In view of this, an objective of the present invention is to propose a testing apparatus and a testing device to improve the testing efficiency, reduce a risk of electrostatic discharge and guarantee the flatness of the testing apparatus.

To this end, the following technical solutions are adopted by the present invention.

In an embodiment, the present invention provides a testing apparatus, which includes:

a platform body;

a supporting plate, fixed on an upper surface of the platform body, and configured to support an array substrate, where the supporting plate comprises a plurality of metal plates arranged along a first direction, each of the metal plates extends along a second direction, and the first direction is intersected with the second direction; and

a conveying apparatus, configured to convey the array substrate.

In another embodiment, the present invention provides a testing device, which includes the testing apparatus provided by the embodiment of the present invention, and a control apparatus connected with the testing apparatus; and

the control apparatus is configured to control the testing apparatus to test an array substrate.

The present invention has the following beneficial effects: according to the testing apparatus and the testing device provided by the present invention, by disposing the supporting plate into the plurality of metal plates arranged along the first direction, and extending each of the metal plates in the second direction, i.e., arranging each of the metal plates into a whole block in the second direction, compared with that the plurality of metal plates respectively spliced by a buckle are disposed in the second direction, the metal plates in the embodiments of the present invention do not need to be spliced, and the adjustment of gaps between the metal plates and a resistance measuring procedure are omitted, and thus a lot of time is saved and the overall testing efficiency is improved; meanwhile, the metal plates are formed into the whole block in the second direction, so there is no problem that a part of positions have an excessively large resistance, and the risk of the electrostatic discharge is reduced; and moreover, as the metal plates are formed into the whole block in the second direction, the problems of an individual difference and a different splicing method of each of the metal plates are prevented, and the flatness of the whole testing apparatus is guaranteed.

### BRIEF DESCRIPTION OF THE DRAWINGS

Hereinafter, exemplary embodiments of the present invention will be described in detail with reference to accompanying drawings, so that the above and other characteristics and advantages of the present invention are clearer to a person of ordinary skill in the art. In the drawings:

FIG. 1 is a planar structural schematic diagram of a testing apparatus;

FIG. 2 is a planar structural schematic diagram of a testing apparatus provided by an embodiment of the present invention;

FIG. 3 is a cross-sectional structural schematic diagram along an A1-A2 direction in FIG. 2;

FIG. 4 is another cross-sectional structural schematic diagram along an A1-A2 direction in FIG. 2;

FIG. 5 is a schematic diagram when an array substrate is supported on a supporting plate provided by an embodiment of the present invention;

FIG. 6 is a cross-sectional structural schematic diagram along a B1-B2 direction in FIG. 5; and

FIG. 7 is a structural schematic diagram of a testing device provided by an embodiment of the present invention.

### DETAILED DESCRIPTION OF THE EMBODIMENTS

The technical solutions of the present invention will be further described below in combination with the accompanying drawings and via specific implementation manners. It may be understood that the specific embodiments described herein are merely for explaining the present invention and are not intended to limit the present invention. Besides, it is further to be noted that only a part but not all of structures relevant to the present invention are shown in the accompanying drawings for the convenience of description.

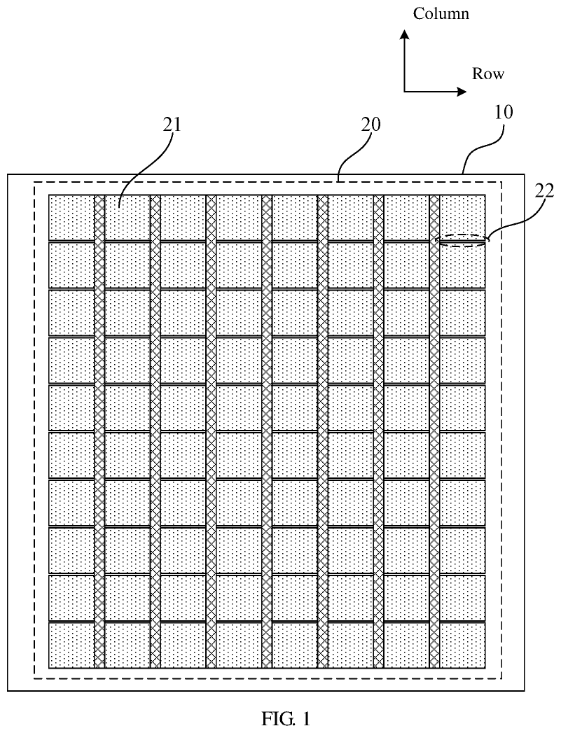

At present, a supporting plate on a stage testing apparatus in a tester is spliced by a plurality of metal plates that are arranged in multiple rows and columns; and adjacent two metal plates on each column are connected via a buckle. Exemplarily, as shown in FIG. 1, a testing apparatus in the tester generally includes a platform body 10, a supporting plate 20 and a conveying apparatus (not shown in figure), where the supporting plate 20 is fixed on an upper surface of the platform body 10, and is configured to support an array substrate; and the conveying apparatus is configured to convey the array substrate. The supporting plate 20 includes a plurality of metal plates 21 arranged along rows and columns in array; a certain gap 22 is provided between adjacent two metal plates 21 on a same column; and the adjacent two metal plates 21 on the same column are connected via a buckle (not shown in figure) at the gap 22. Since it is not ensured that a resistance at a junction of the adjacent two metal plates 21 on the same column is within a specified range, the gap 22 between the adjacent two metal plates 21 on the same column needs to be adjusted, and whenever a chamber of the tester is opened, the resistance at the junction needs to be measured, thereby being time-consuming. With an excessively large resistance at the junction, there may be an electrostatic focus and a risk of electrostatic discharge, and a to-be-tested product (array substrate) may be damaged. In addition, due to an individual difference of each of the metal plates 21 and a splicing influence, the flatness of the whole testing apparatus cannot be guaranteed and the detection on the to-be-tested product is affected.

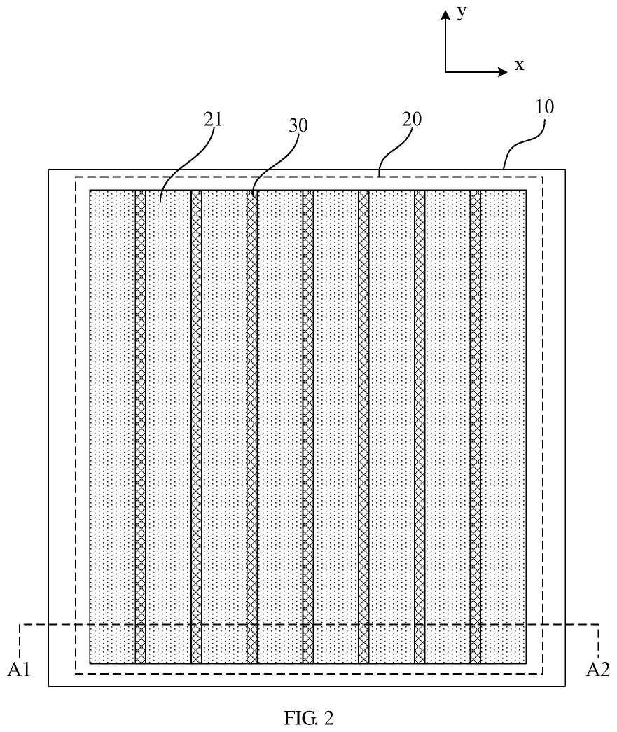

Concerning the above-mentioned problems, an embodiment of the present invention provides a testing apparatus, which may implement a performance test on an array assembly. FIG. 2 is a planar structural schematic diagram of a testing apparatus provided by an embodiment of the present invention. As shown in FIG. 2, the testing apparatus includes:

a platform body 10;

a supporting plate 20, fixed on an upper surface of the platform body 10, and configured to support an array substrate, where the supporting plate 20 comprises a plurality of metal plates 21 arranged along a first direction x, each of the metal plates 21 extends along a second direction y, and the first direction x is intersected with the second direction y; and

a conveying apparatus, configured to convey the array substrate.

The conveying apparatus includes a plurality of conveying shafts 30; each of the conveying shafts 30 is disposed between any adjacent two metal plates 21; and

the conveying shafts 30 are fixed on the upper surface of the platform body 10; and each of the conveying shafts 30 rotates around a central shaft, and is configured to convey the array substrate along the first direction x.

The testing apparatus is located in a vacuum chamber of the testing device; the vacuum chamber is opened, the conveying apparatus is started, the conveying shafts 30 rotate, and a to-be-detected array substrate is pushed from one side, located in the first direction x, of the supporting plate 20; and when the array substrate is carried on the conveying shafts 30, the conveying shafts 30 push the array substrate along the first direction x till the array substrate is completely located on the supporting plate 20. By adjusting the conveying apparatus appropriately, the array substrate is located in a detection zone.

According to the testing apparatus provided by this embodiment, by disposing the supporting plate into the plurality of metal plates arranged along the first direction, and extending each of the metal plates in the second direction, i.e., arranging each of the metal plates into a whole block in the second direction, compared with that the plurality of metal plates respectively spliced by a buckle are disposed in the second direction, the metal plates in this embodiment of the present invention do not need to be spliced, and the adjustment of gaps between the metal plates and a resistance measuring procedure are omitted, and thus a lot of time is saved and the overall testing efficiency is improved; meanwhile, the metal plates are formed into the whole block in the second direction, so there is no problem that a part of positions have an excessively large resistance, and the risk of the electrostatic discharge is reduced; and moreover, as the metal plates are formed into the whole block in the second direction, the problems of an individual difference and a different splicing method of each of the metal plates are prevented, and the flatness of the whole testing apparatus is guaranteed.

Optionally, the conveying apparatus further includes a conveying drive apparatus; and the conveying drive apparatus is electrically connected with the plurality of conveying shafts, and is configured to drive the plurality of conveying shafts to rotate.

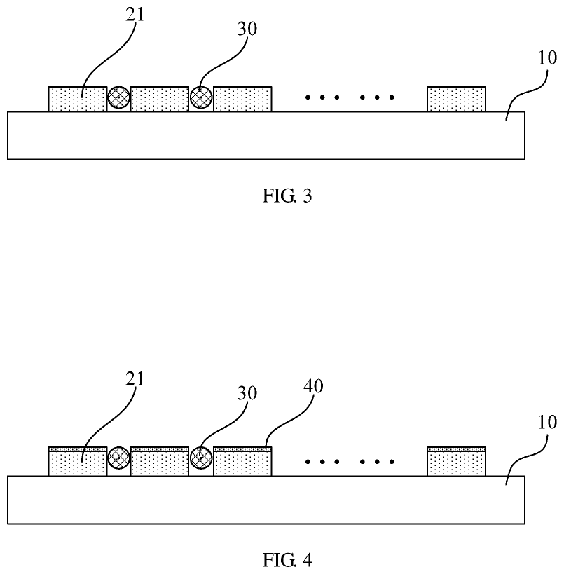

Optionally, referring to FIG. 3, in the above solution, a portion where each of the conveying shafts 30 contacts the array substrate is flush with a surface of a side, far away from the platform body 10, of each of the metal plates 21. Therefore, the flatness of the whole testing apparatus may be guaranteed. The array substrate may be conveyed along the first direction; and furthermore, the array substrate may be attached to the surface of the side, far away from the platform body 10, of each of the metal plates 12 to perform detection on the array substrate.

FIG. 4 is another cross-sectional structural schematic diagram along an A1-A2 direction in FIG. 2. As shown in FIG. 4, in this embodiment, an electrostatic tape 40 is attached to the surface of the side, far away from the platform body 10, of each of the metal plates 21. Each of the electrostatic tapes 40 may include an electrostatic film and an anti-electrostatic film; the electrostatic film is attached via a static electricity to the surface of the side, far away from the platform body 10, of each of the metal plates 21; and the anti-electrostatic film has an anti-electrostatic effect, so that the array substrate may be prevented from suffering an electrostatic damage in a detection process. In addition, since each of the electrostatic tapes 40 is very thin, the portion where each of the conveying shafts 30 contacts the array substrate may be flush with the surface of the side, far away from the platform body 10, of each of the metal plates 21. Certainly, in order to prevent each of the conveying shafts 30 from sliding in rotation, a height or a size of each of the conveying shafts 30 may also be adjusted, so that the portion where each of the conveying shafts 30 contacts the array substrate is flush with a surface of a side, far away from the platform body 10, of each of the electrostatic tapes 40.

Optionally, two ends of each of the conveying shafts 30 may be rotatably disposed on an ascending-descending bracket; and each of the conveying shafts 30 is fixed on the upper surface of the platform body 10 via the bracket. By adjusting the bracket to ascend and descend, each of the conveying shafts 30 may be adjusted to a required height. Therefore, while the reliability of each of the conveying shafts 30 is improved, the flatness of the whole testing apparatus is guaranteed.

Optionally, referring to FIG. 2 continuously, a length of each of the metal plates 21 in the second direction y is greater than a length of each of the metal plates 21 in the first direction x.

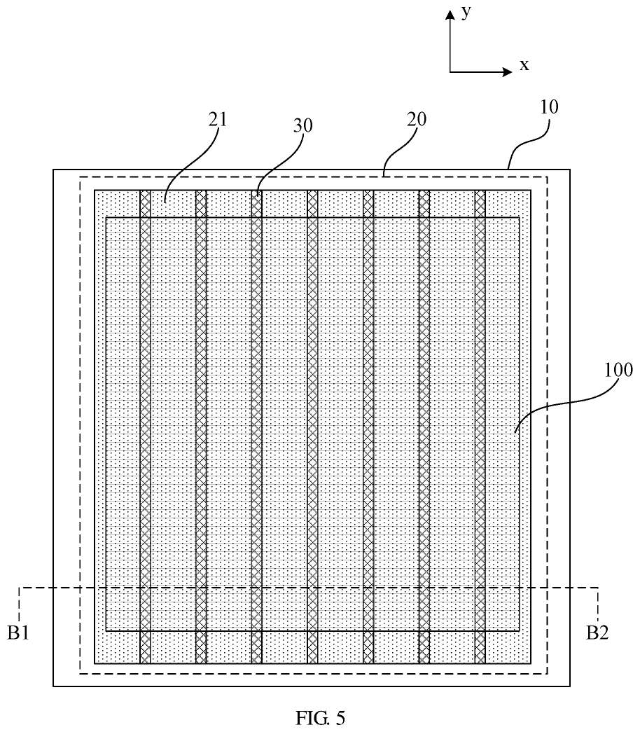

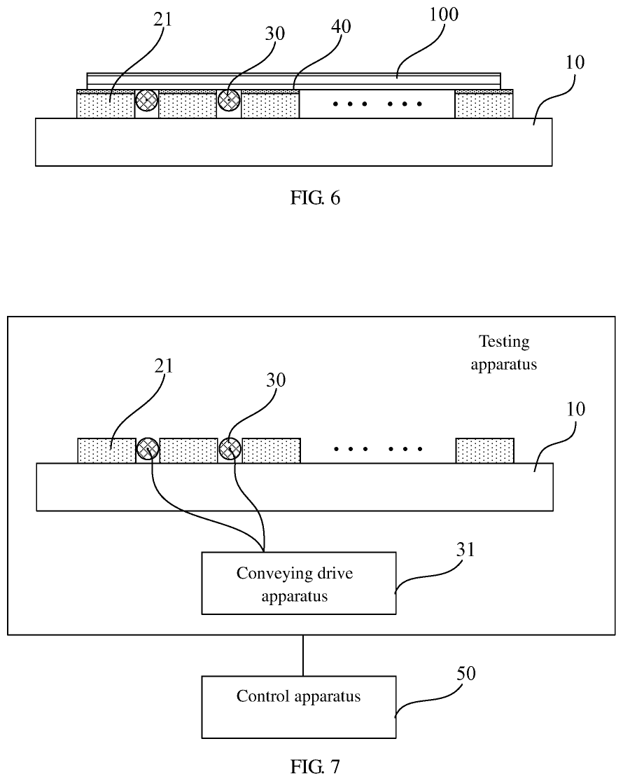

Exemplarily, referring to FIG. 5, the length of each of the metal plates 21 in the second direction y is greater than or equal to a length of the placed array substrate 100 in the second direction, so that the array substrate 100 may be completely attached to the supporting plate to be conveyed. Referring to FIG. 6, a length of the supporting plate in the first direction x is greater than or equal to a length of the placed array substrate 100 in the first direction x, so that the array substrate 100 may be completely placed on the supporting plate to perform detection on the array substrate 100.

Optionally, each of the metal plates 21 is of a rectangular shape; the metal plates 21 are arranged in parallel along the first direction x; and the first direction x is perpendicular to the second direction y. Therefore, the supporting plate formed by the metal plates 21 is of the rectangular shape, so that an effective supporting area of the supporting plate may be increased.

Optionally, in the above solution, each of the metal plates 21 is the same in size. At this time, each of the metal plates 12 may be manufactured by a same mould, so that the thickness and the flatness of each of the metal plates 21 may be guaranteed to be consistent, thereby further improving the flatness of the whole testing apparatus. In addition, each of the metal plates 21 may be cut apart from a whole block of metal plate, so that the thickness and the flatness of each of the metal plates 21 may also be guaranteed to be consistent, thereby improving the flatness of the whole testing apparatus.

An embodiment of the present invention further provides a testing device. As shown in FIG. 7, the testing device includes the testing apparatus in the above embodiment, and a control apparatus 50 connected with the testing apparatus; and

the control apparatus 50 is configured to control the testing apparatus to test an array substrate.

Optionally, the testing apparatus includes: a platform body 10, a supporting plate 20 and a conveying apparatus; the supporting plate 20 is fixed on an upper surface of the platform body 10, and is configured to support the array substrate; the supporting plate 20 includes a plurality of metal plates 21 arranged along a first direction; each of the metal plates 21 extends along a second direction; and the conveying apparatus is configured to convey the array substrate. The conveying apparatus includes a conveying drive apparatus 31 and a plurality of conveying shafts 30; the conveying drive apparatus 31 is electrically connected with the plurality of conveying shafts 30, and is configured to drive the plurality of conveying shafts 30 to rotate; each of the conveying shafts 30 is disposed between any adjacent two metal plates 21; the conveying shafts 30 are fixed on the upper surface of the platform body 10; and the conveying shafts 30 rotates around a central shaft, and are configured to convey the array substrate along the first direction x.

Optionally, the control apparatus 50 is electrically connected with the conveying drive apparatus 31, and is configured to send a drive control signal to the conveying drive apparatus 31; and the conveying drive apparatus 31 drives the plurality of conveying shafts 30 according to the drive control signal to rotate correspondingly.

In the testing device provided by this embodiment, by disposing the supporting plate into the plurality of metal plates arranged along the first direction, and extending each of the metal plates in the second direction, i.e., arranging each of the metal plates into a whole block in the second direction, compared with that the plurality of metal plates respectively spliced by a buckle are disposed in the second direction, the metal plates in this embodiments of the present invention do not need to be spliced, and the adjustment of gaps between the metal plates and a resistance measuring procedure are omitted, and thus a lot of time is saved and the overall testing efficiency is improved; meanwhile, the metal plates are formed into the whole block in the second direction, so there is no problem that a part of positions have an excessively large resistance, and the risk of the electrostatic discharge is reduced; and moreover, as the metal plates are formed into the whole block in the second direction, the problems of an individual difference and a different splicing method of each of the metal plates are prevented, and the flatness of the whole testing apparatus is guaranteed.

In the above solution, the array substrate is constituted as a part of a display panel. The display panel may be used for manufacturing a mobile terminal; and the mobile terminal may be an intelligent mobile phone, a tablet computer or a personal digital assistant.

It is to be noted that the above only are preferred embodiments and technical principles of the present invention. It should be understood by a person skilled in the art that the present invention is not limited to the specific embodiments described herein, and various apparent changes, readjustments, mutual combinations and replacements may be made by the person skilled in the art without departing from a scope of protection of the present invention. Therefore, although the present invention is described in detail with the above embodiments, the present invention is not only limited to the above embodiments, and may include more other equivalent embodiments without departing from the concept of the present invention. The scope of the present invention is subject to the appended claims.

What is claimed is:

1. A testing apparatus, comprising:
a platform body;
a supporting plate, fixed on an upper surface of the platform body, and configured to support an array substrate, wherein the supporting plate comprises a plurality of metal plates arranged along a first direction, each of the metal plates extends along a second direction, and the first direction is intersected with the second direction; and
a conveying apparatus, configured to convey the array substrate.

2. The testing apparatus according to claim 1, wherein the conveying apparatus comprises a plurality of conveying shafts; each of the conveying shafts is disposed between any adjacent two metal plates; and
the conveying shafts are fixed on the upper surface of the platform body; and each of the conveying shafts rotates around a central shaft, and is configured to convey the array substrate along the first direction.

3. The testing apparatus according to claim 2, wherein a portion where each of the conveying shafts contacts the array substrate is flush with a surface of a side, far away from the platform body, of each of the metal plates.

4. The testing apparatus according to claim 1, wherein an electrostatic tape is attached to the surface of the side, far away from the platform body, of each of the metal plates.

5. The testing apparatus according to claim 1, wherein a length of each of the metal plates in the second direction is greater than a length of each of the metal plates in the first direction.

6. The testing apparatus according to claim 5, wherein the length of each of the metal plates in the second direction is greater than or equal to a length of the placed array substrate in the second direction.

7. The testing apparatus according to claim 1, wherein each of the metal plates is of a rectangular shape; and the metal plates are arranged in parallel along the first direction.

8. The testing apparatus according to claim 1, wherein the first direction is perpendicular to the second direction.

9. The testing apparatus according to claim 1, wherein each of the metal plates is different in size.

10. A testing apparatus, comprising:
a platform body;
a supporting plate, fixed on an upper surface of the platform body, and configured to support an array substrate, wherein the supporting plate comprises a plurality of metal plates arranged along a first direction, each of the metal plates extends along a second direction, and the first direction is intersected with the second direction; and
a conveying apparatus, configured to convey the array substrate, wherein the conveying apparatus comprises a plurality of conveying shafts, each of the conveying shafts is disposed between any adjacent two metal plates, the conveying shafts are fixed on the upper surface of the platform body, and each of the conveying shafts rotates around a central shaft, and is configured to convey the array substrate along the first direction, and an electrostatic tape is attached to the surface of the side, far away from the platform body, of each of the metal plates.

11. A testing device, comprising the testing apparatus and a control apparatus connected with the testing apparatus, wherein the testing apparatus comprises:
a platform body;
a supporting plate, fixed on an upper surface of the platform body, and configured to support an array substrate, wherein the supporting plate comprises a plurality of metal plates arranged along a first direction, each of the metal plates extends along a second direction, and the first direction is intersected with the second direction; and
a conveying apparatus, configured to convey the array substrate; and
the control apparatus is configured to control the testing apparatus to test the array substrate.

12. The testing device according to claim 11, wherein the conveying apparatus comprises a plurality of conveying shafts; each of the conveying shafts is disposed between any adjacent two metal plates; and
the conveying shafts are fixed on the upper surface of the platform body; and each of the conveying shafts rotates around a central shaft, and is configured to convey the array substrate along the first direction.

13. The testing device according to claim 12, wherein a portion where each of the conveying shafts contacts the array substrate is flush with a surface of a side, far away from the platform body, of each of the metal plates.

14. The testing device according to claim 11, wherein an electrostatic tape is attached to the surface of the side, far away from the platform body, of each of the metal plates.

15. The testing device according to claim 11, wherein a length of each of the metal plates in the second direction is greater than a length of each of the metal plates in the first direction.

16. The testing device according to claim 15, wherein the length of each of the metal plates in the second direction is greater than or equal to a length of the placed array substrate in the second direction.

17. The testing device according to claim 11, wherein each of the metal plates is of a rectangular shape; and the metal plates are arranged in parallel along the first direction.

18. The testing device according to claim 11, wherein the first direction is perpendicular to the second direction.

19. The testing device according to claim 11, wherein each of the metal plates is different in size.

20. The testing device according to claim 11, wherein the testing apparatus comprises:
the conveying shafts are fixed on the upper surface of the platform body; each of the conveying shafts rotates around the central shaft, and is configured to convey the array substrate along the first direction; and the electrostatic tape is attached to the surface of the side, far away from the platform body, of each of the metal plates.
